(19) United States
(12) Patent Application Publication
(10) Pub. No.: US 2021/0217914 A1
(43) Pub. Date: Jul. 15, 2021

(54) PHOTOVOLTAIC PANEL AND A MINICHANNEL COOLER SOLAR COLLECTOR COMBINATION (PV-T)

(71) Applicant: Rahim JAFARI, Çankaya/Ankar (TR)

(72) Inventor: Rahim JAFARI, Ankara (TR)

(21) Appl. No.: 17/250,108

(22) PCT Filed: Sep. 13, 2019
(86) PCT No.: PCT/TR2019/050749

§ 371 Date: Nov. 27, 2020

(30) Foreign Application Priority Data
Sep. 24, 2018 (TR) 2018/13797

(51) Int. Cl. H01L 31/052; H02S 40/42

(52) U.S. Cl. CPC H01L 31/0521; H02S 40/425

(57) ABSTRACT

A photovoltaic solar panel is provided. The photovoltaic solar panel includes a glass positioned in front of photovoltaic solar cells in order to provide environmental protection, an adhesive used in the solar panel, an array of soldered photovoltaic solar cells which generates electricity, a mini/micro channel cooler configured to remove heat from the photovoltaic solar cells and being adhered right behind the photovoltaic solar cell by the adhesive, Tedlar Polyester Tedlar (TPT) adhered to the cooler by the adhesive for environmental protection, an insulator having a thermal structure configured to use when the solar panel is connected to a container to warm up water inside the container, a cover positioned below the insulator and being configured to protect the insulator from humidity and medium harmful effects, a circulating pump configured to circulate coolant from the cooler to the container, and a polymer tube configured to remove the heat from the panel to the ground.

### TECHNICAL FIELD OF THE INVENTION

The invention is related to a solar panel having a photovoltaic panel and a mini/micro channel cooler, solar collector, combination (pv-t).

### KNOWN STATE OF THE ART (PRIOR ART)

Nowadays there are a few companies which produce the existing Photovoltaic-thermal (PV-T) panels. These companies generally use monocrystalline or polycrystalline photovoltaic cells in order to produce electricity. However, the cells cooling methods and heat dissipation systems are different. Some companies have mounted a copper sheet behind the PV panels. A helical copper pipe has been welded to the backside of the panel. Water flows through the copper pipe and enables the PV panel heat to be carried into a different water tank. Another company used an aluminum plate behind the PV panel and the cooling liquid (water) circulation is provided with helical channels and fins. A cooler with a polypropylene channels has been placed at the bottom section of the PV cells in another product. In the patent numbered US20130042902A1 it is enabled for fluid to flow between the photovoltaic array and the transparent top layer. The working fluid is disinfected by a photocatalytic disinfectant layer provided on a light transmitting surface contacting the working fluid. According to the PV solar panel of the patent numbered WO2018053579A1 a heat sink has been placed behind each PV cells. A plurality of heat sink tiles which enables the flow of the heat exchanger of the cooling fluid are connected to the circulation system. In the invention numbered WO2013025094A2, the cooling of PV cells are enabled by a blower blowing air through the honeycomb structure that has been placed behind the PV panel. In the top cooling construction of the invention numbered 2013/07786, a photovoltaic panel is placed at the top entrance section of the textile surface whose bottom surface has been coated with a water impermeable layer or laminated textile surface and the slit or perforated pipe where cold water is transferred to the collector has been placed such that its slits or perforations face the top section of the front face of the photovoltaic panel. Therefore the cold water which is received by the collector first of all flows by grazing the front face of the PV cells and it also becomes warmer itself while trying to cool the PV cells and then it becomes even warmer while it continues to flow inside the black textile surface which has heated up from solar rays and it then leaves the collector from an outlet located at the mid section of the collector. In the construction with bottom cooling, the photovoltaic PV panel is placed at the top section of the textile based flexible solar collector such that the top layer of the transparent bag located outside the flexible collector completely contacts the PV panel from the bottom and therefore it is enabled for the water flowing through the textile surface to cool the PV panel from the bottom.

As the density (8900 Kg/m3) of copper and its price are high, the weight and the costs of Solimpeks® panels increase. Moreover the panel thickness increases up to 95 mm. Other companies have used Aluminum (2300 Kg/m3) which its density and price are lower. A different process has been carried out on an aluminum plate in some products and the circulation of the cooling liquid is enabled by channels and fins (Anafsolar®). The weight (heat sink+coolant) of all aforementioned products are higher than 30 Kg and this causes disadvantages as the panels are generally installed on roofs or high places. Moreover the processing cost of the cooling material also becomes high. Dualsun® (patent number: WO2016156764) uses polypropylene, a thermoplastic material, as the heat sink material which has low thermal conductivity (0.1-0.2 W/m/K) and it transfers lower amounts of heat in comparison to metal coolers. Also the coolant flows through longitudinal channels from one side of the panel to the other side.

One of the most important problems of photovoltaic (PV) solar panels, is that the temperature of the PV panel increases as a result of the absorbance of the solar ray and this leads to reduction of efficiency and the technical life of the panel. In commercial versions PV nominal efficiencies are lower than 20%. This low efficiency falls further as the working temperature of the PV panels increases. This means that the remaining 80% energy is waste energies for PV modules.

### BRIEF DESCRIPTION OF THE INVENTION

The present invention relates to a photovoltaic solar panel and a mini/micro channel cooler solar collector combination (pv-t) in order to provide new advantages to the related technical field and to eliminate the above mentioned disadvantages.

The cooler formed of micro/mini channels has been adhered right behind the Photovoltaic solar cell. The minichannels and the microchannels have higher heat transfer capability as they have a higher ratio of the area to the volume. This feature of the cooler makes it possible to remove more heat from the cells in comparison to other similar products. As a result PV cells are cooled even more and they operate with higher efficiency. Additionally as the thickness of the channels is smaller, the volume of the coolant inside the cooler is lower and as a result it is lighter when compared with other products. The heat collected from the Photovoltaic solar cells by circulating coolant is transferred into the water container and heats up the water inside the container. Alternatively, the collected heat from the PV cells can be dissipated to the ground by buried plastic tubes. Since the temperature of the ground about 4 m down is between 10° C.-16° C., it is possible to transfer the heat from the hot PV cells to the ground. The liquid coolant (water+ethylene glycol) which has lost its heat is pumped back to the cooler and this cycle is repeated. Waste energy can also be used for heating indoor places and heating of water (villas, houses, hotels, hospitals, sports facilities, offices, etc.) The invention can meet both the electric and thermal energy requirements of the industry.

### BRIEF DESCRIPTION OF THE FIGURES

FIG. 1, shows a photovoltaic panel and a mini/micro channel cooler solar thermal collector combination (pv-t).

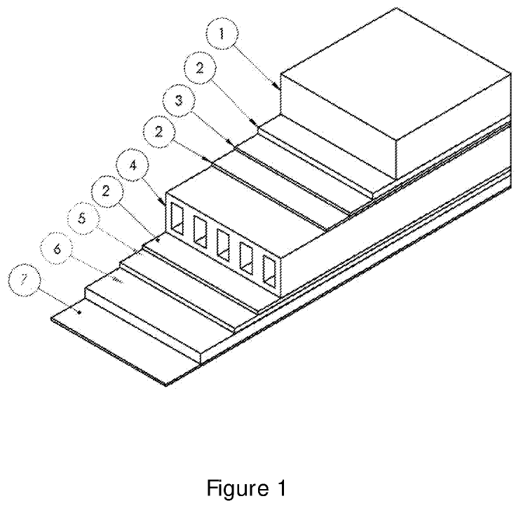

FIG. 2, shows the solar panel, buried polymer pipe and circulating pump.

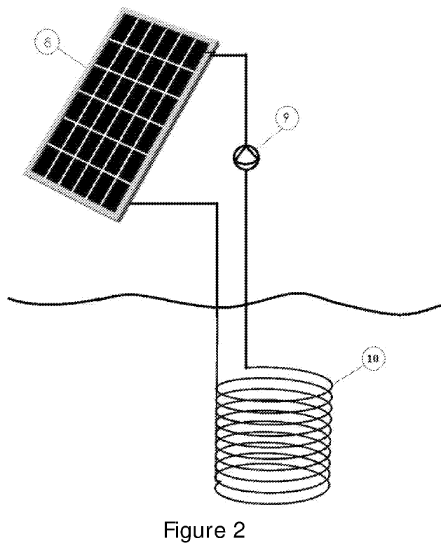

### REFERENCE NUMBERS

1 Glass
2 Adhesive
3 Photovoltaic solar cells
4 Mini/micro channel Cooler
5 Tedlar Polyester Tedlar (TPT)
6 Insulator
7 Cover
8 Photovoltaic panel and mini/micro channel combination
9 Circulating pump
10 Polymer tube

### DETAILED DESCRIPTION OF THE INVENTION

In this detailed description the novelty subject to the invention is described by means of examples that are non-limiting but are intended to further describe the invention.

The invention is a photovoltaic-thermal solar panel, related to a photovoltaic panel and a mini/micro channel cooler solar collector combination (pv-t) (8). In order to provide environmental protection, a glass (1) is adhered in front of the Photovoltaic solar cells (3) by an adhesive (2) such as EVA (Ethylene Vinyl Acetate). An aluminum or polymer mini/microchannels cooler (4) formed of mini or micro channels has been adhered right behind the Photovoltaic solar cell (3) by adhesive (2) such as EVA (Ethylene Vinyl Acetate). The height of each channel is between 0.4-2 mm and the width is 0.5-5 mm. The overall width of the channels which the coolant enters is about between 125-156 mm (dimensions of Photovoltaic (PV) cells). The coolant flows in the mini/micro channel cooler (4) through the channels, alongside of the panel length, and turns round in serpentine shape to the next rows of channels along the panel length just under the PV cells. Minichannels and microchannels have higher heat transfer capability as the ratio of the area to the volume is high. The cooler has such a feature and therefore it can remove more heat from the cells in comparison to other similar products. Additionally as the thickness of the channels is small, the volume of the cooler is low and consequently it is lighter compared with other products. The heat received by the Photovoltaic solar cells (3) is carried to the water container after a cycle and it then heats the water inside the container. This liquid (water+ethylene glycol) which has lost its heat is pumped back to the cooler and this cycle is repeated. Alternatively, the extracted heat from photovoltaic panel and a mini/micro channel cooler solar collector combination (pv-t) (8) would be dissipated to the ground by buried polymer pipes or polymer tubes (10). This way, the PV cells of solar panel are maintained cool and consequently the electrical efficiency and lifetime will increase. The materials used for producing PV-T solar panels have been placed on top of each other as layers and have been mounted in about 25 minutes at a temperature of about 140° C. These materials are respectively glass (1), transparent adhesive (2) such as EVA (Ethylene Vinyl Acetate), an array of soldered photovoltaic solar cells (3) and adhesive (2) the mini/micro channel cooler (4), adhesive (2), and Tedlar Polyester Tedlar (TPT) (5). In the case of heat storage in a container, a thermal insulator (6) placed inside a metal frame is enclosed with a cover (7). The mini/micro channel cooler (4) has a structure formed of aluminum or polymer material. Mini/micro channel cooler (4) is made of aluminum or polymer material by extrusion method.

The insulator (6) (if the cooler is used to store the transferred heat to a container) is used when the solar panel is connected to the container to warm up the water of inside it. Otherwise, the insulator (6) and the cover (7) will not be used in the panel. The cover (7) is used to protect the insulator from humidity and medium harmful effects. So when the panel is connected to the polymer pipe/Polymer tube (10) in the ground, the cover (7) and the insulator (6) will be removed. The EVA is an adhesive (2). It is a common adhesive material which is used in the solar panels.

According to the description above, the invention is a photovoltaic solar panel made up of photovoltaic solar cells and a mini/micro channel cooler solar collector combination (pv-t) (8), characterized by comprising;
A glass (1) which is positioned in front of photovoltaic solar cells (3) in order to provide environmental protection,
Adhesive (2) which is used in the solar panel,
An array of soldered photovoltaic solar cells (3) which generates electricity,
Mini/micro channel Cooler (4) which is providing to remove more heat from the cells and which have been adhered right behind the Photovoltaic solar cell (3) by adhesive (2),
Tedlar Polyester Tedlar (TPT) (5) which have been adhered to the cooler by adhesive (2) for environmental protection,
Insulator (6) which is having a thermal structure, is used when the solar panel is connected to the container to warm up the water of inside it,
A cover (7) which is positioned below the insulator (6), is used to protect the insulator from humidity and medium harmful effects,
Circulating pump (9) which is used to circulate the coolant from the cooler to the container/buried tube,
Polymer tube (10) which is used to remove the heat from the panel to the ground.

1. A photovoltaic solar panel comprising:
a glass positioned in front of photovoltaic solar cells in order to provide environmental protection,
an adhesive used in the solar panel,
an array of soldered photovoltaic solar cells which generates electricity,
a mini/micro channel cooler configured to remove heat from the photovoltaic solar cells and being adhered right behind the photovoltaic solar cell by the adhesive,
Tedlar Polyester Tedlar (TPT) adhered to the cooler by the adhesive for environmental protection,
an insulator having a thermal structure configured for use when the solar panel is connected to a container to warm up water inside the container,
a cover positioned below the insulator and being configured to protect the insulator from humidity and medium harmful effects,
a circulating pump configured to circulate coolant from the cooler to the container, and
a polymer tube configured to remove the heat from the panel to the ground.

2. The photovoltaic solar panel according to claim 1, wherein the mini/micro channel cooler comprises micro or mini channels.

3. The photovoltaic solar panel according to claim 2, wherein each channel comprises a height between 0.4-2 mm and a width between 0.5-5 mm.

4. The photovoltaic solar panel according to claim 2, wherein the channels, in which the coolant enters, comprises an overall width between 125-156 mm.

5. The photovoltaic solar panel according to claim 2, wherein the coolant flows in the mini/micro channel cooler through the channels, alongside a panel length, and turns round in serpentine shape to subsequent rows of channels along the panel length just under the photovoltaic solar cells.

6. The photovoltaic solar panel according to claim 1, wherein the mini/micro channel cooler comprises aluminum or an extruded polymer material.

7. The photovoltaic solar panel according to claim 1, wherein extracted heat from the panel is dissipated to the ground via the polymer tube, wherein the polymer tube is buried.

8. The photovoltaic solar panel according to claim 1, wherein the adhesive adheres the photovoltaic solar cells to the glass and adheres the mini/micro channel cooler right behind the photovoltaic solar cell.

9. photovoltaic solar panel according to claim 1, wherein the adhesive comprises an ethylene vinyl acetate.
